(19) United States
(12) Patent Application Publication
(10) Pub. No.: US 2015/0228538 A1
(43) Pub. Date: Aug. 13, 2015

(54) SEMICONDUCTOR DEVICE AND MANUFACTURING METHOD THEREOF

(71) Applicant: KABUSHIKI KAISHA TOSHIBA, Tokyo (JP)

(72) Inventors: Makoto WADA, Yokkaichi-Shi (JP); Akihiro KAJITA, Yokkaichi-Shi (JP); Atsunobu ISOBAYASHI, Yokkaichi-Shi (JP); Tatsuro SAITO, Yokkaichi-Shi (JP); Taishi ISHIKURA, Yokkaichi-Shi (JP)

(21) Appl. No.: 14/444,696

(22) Filed: Jul. 28, 2014

Related U.S. Application Data
(60) Provisional application No. 61/938,532, filed on Feb. 11, 2014.

(51) Int. Cl. H01L 21/768; H01L 23/522; H01L 23/528

(52) U.S. Cl. CPC H01L 21/76879; H01L 21/76805; H01L 21/76883; H01L 23/528; H01L 23/5226

(57) ABSTRACT

According to one embodiment, a semiconductor device includes a semiconductor substrate, an interlayer insulation film, a plug, a first mark, a second mark, and an upper wiring. The substrate has a device region and a mark formation region. The interlayer insulation film is formed on the substrate. The plug is made of a first metal material in the interlayer insulation film on the device region of the substrate. The first mark is made of the first metal material in the interlayer insulation film on the mark formation region of the substrate. The second mark is made of a second metal material in the interlayer insulation film on the mark formation region of the substrate. The second mark has a concave on a surface thereof. The upper wiring is formed on the interlayer insulation film and is electrically connected to the plug.

### CROSS REFERENCE TO RELATED APPLICATION(S)

This application is based upon and claims the benefit of priority from the prior U.S. Provisional Patent Application No. 61/938,532, filed on Feb. 11, 2014, the entire contents of which are incorporated herein by reference.

### FIELD

Embodiments described herein relate generally to a semiconductor device and manufacturing method thereof.

### BACKGROUND

Conventionally, when an upper wiring is formed on contact plugs in a semiconductor device, alignment between the contact plugs and an upper wiring layer is performed by using steps of alignment marks as references.

### BRIEF DESCRIPTION OF THE DRAWINGS

FIG. 1 is a cross-sectional view showing an example of a configuration of a semiconductor device according to a first embodiment;

FIGS. 2 to 9 are cross-sectional views showing an example of a manufacturing method of the semiconductor device shown in FIG. 1;

FIG. 10 is a cross-sectional view showing an example of a configuration of a semiconductor device according to a second embodiment;

FIGS. 11 to 16 are cross-sectional views showing an example of a manufacturing method of the semiconductor device shown in FIG. 10;

FIG. 17 is a cross-sectional view showing an example of a configuration of a semiconductor device according to a third embodiment; and

FIGS. 18A and 18B are plan views showing an example of shapes of a first alignment mark and a second alignment mark.

### DETAILED DESCRIPTION

Embodiments will now be explained with reference to the accompanying drawings. The present invention is not limited to the embodiments. In the embodiments, “an upper direction” or “a lower direction” refers to a relative direction when a direction of a surface of a semiconductor substrate on which semiconductor elements are provided is assumed as “an upper direction”. Therefore, the term “upper direction” or “lower direction” occasionally differs from an upper direction or a lower direction based on a gravitational acceleration direction.

In recent years, along with downscaling of semiconductor devices, the aspect ratio of via holes of contact plugs has increased. Therefore, when the via holes are embedded with a metal material using a CVD (Chemical Vapor Deposition) method, the metal material is deposited conformally from side surfaces of openings of the via holes and thus seams or voids (hereinafter, “seams or the like”) may be formed at central portions of the contact plugs. The seams or the like formed within the contact plugs have problems because the seams or the like cause increase in the resistances of the contact plugs or poor conduction thereof.

To handle such problems, there is a method of forming contact plugs by an electroless plating method or the like. In this case, because a metal material grows from bottoms of via holes toward openings thereof, it is possible to prevent seams or the like from being formed. However, in this case, concaves of alignment marks are also embedded with the metal material. As a result, the concaves are not formed on surfaces of the alignment marks. Further, because a material for an upper wiring (for example, a metal) does not generally transmit light, it is also impossible to optically check a contrast between the alignment marks and an interlayer insulation film. As a result, there is a problem that it is difficult to perform alignment between the contact plugs and an upper wiring layer by using the alignment marks.

According to the present embodiment, a semiconductor device includes a semiconductor substrate, an interlayer insulation film, a plug, a first mark, a second mark, and an upper wiring. The semiconductor substrate has a device region and a mark formation region. The interlayer insulation film is formed on the semiconductor substrate. The plug is made of a first metal material in the interlayer insulation film on the device region of the semiconductor substrate. The first mark is made of the first metal material in the interlayer insulation film on the mark formation region of the semiconductor substrate. The second mark is made of a second metal material in the interlayer insulation film on the mark formation region of the semiconductor substrate. The second mark has a concave on a surface thereof. The upper wiring is formed on the interlayer insulation film and is electrically connected to the plug.

### First Embodiment

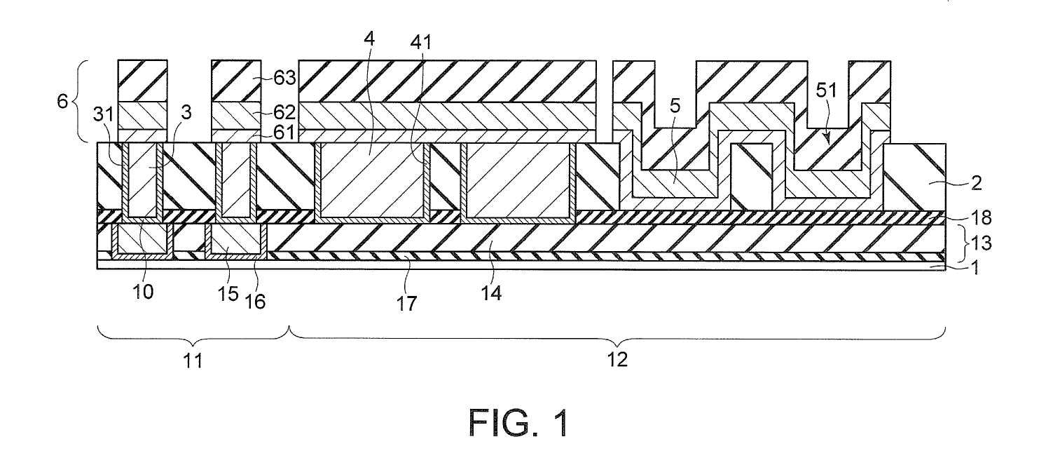

A semiconductor device according to a first embodiment and a manufacturing method thereof are explained below with reference to FIGS. 1 to 9. FIG. 1 is a cross-sectional view showing an example of a configuration of the semiconductor device according to the first embodiment. As shown in FIG. 1, the semiconductor device according to the first embodiment includes a semiconductor substrate 1, a lower wiring layer 13, an interlayer insulation film 2, contact plugs 3, first alignment marks 4, second alignment marks 5, and an upper wiring layer 6.

The semiconductor substrate 1 is made of Si or the like. Semiconductor elements such as a transistor and a capacitor (both are not shown) are formed on the semiconductor substrate 1. The semiconductor substrate 1 includes a device region 11 and a region 12 where marks are formed (hereinafter, “mark formation region 12”). The device region 11 is a region where the semiconductor elements mentioned above are formed. The mark formation region 12 is a region where these semiconductor elements are not formed. Out of a region on the semiconductor substrate 1 where the semiconductor elements can be formed, a region except for the device region 11 is included in the mark formation region 12. A dicing region can be included in the mark formation region 12. As shown in FIG. 1, the lower wiring layer 13 is formed on a surface of the semiconductor substrate 1.

The lower wiring layer 13 includes an insulation film 14, a lower wiring 15, a barrier film 16, and a stopper insulation film 17. The insulation film 14 is made of an insulator such as SiO₂. The lower wiring 15 is formed by embedding a metal material such as Al, Cu, or W into an opening formed in the insulation film 14. The lower wiring 15 is formed above the device region 11 of the semiconductor substrate 1 and electrically connected to the semiconductor elements mentioned above formed on the semiconductor substrate 1.

The barrier film 16 is formed between the insulation film 14 and the lower wiring 15. The barrier film 16 is made of a barrier metal such as Ti or TiN and suppresses diffusion of a metal material that forms the lower wiring 15 to the insulation film 14. The lower wiring 15 is connected via the barrier film 16 to the semiconductor elements. The stopper insulation film 17 made of SiN or the like is formed between the insulation film 14 and the semiconductor substrate 1. A stopper insulation film 18 made of SiN or the like is formed on the insulation film 14.

The semiconductor device according to the first embodiment can also be configured without the barrier film 16 and the stopper insulation film 17, or can also be configured in such a manner that semiconductor elements instead of the lower wiring 15 are formed in the lower wiring layer 13.

The interlayer insulation film 2 made of an insulator such as SiO₂ is formed on the stopper insulation film 18. The contact plugs 3, the first alignment marks 4, and the second alignment marks 5 are formed in the interlayer insulation film 2. That is, the contact plugs 3, the first alignment marks 4, and the second alignment marks 5 are formed in the same layer (the interlayer insulation film 2).

The contact plugs 3 are formed in the interlayer insulation film 2 on the device region 11 of the semiconductor substrate 1. More specifically, the contact plugs 3 are formed by embedding a first metal material into openings formed in the interlayer insulation film 2 on the device region 11 of the semiconductor substrate 1. Cu, Al, Ni, W, Co, Mo, Ru, or an alloy thereof can be used as the first metal material. The first metal material can be selected depending on a method of forming the contact plugs 3. The size of the contact plugs 3 can be designed arbitrarily. For example, the width of the contact plugs 3 can be 10 nm to 20 nm.

A barrier film 31 is formed between the contact plugs 3 and the interlayer insulation film 2. The barrier film 31 is made of a barrier metal such as Ti or TiN and suppresses diffusion of the first metal material that forms the contact plugs 3 to the interlayer insulation film 2.

The contact plugs 3 are electrically connected via the barrier film 31 to the lower wiring 15. The semiconductor device according to the first embodiment can also be configured without the barrier film 31.

The first alignment marks 4 (hereinafter, “marks 4”) are formed in the interlayer insulation film 2 on the mark formation region 12 of the semiconductor substrate 1. More specifically, the marks 4 are formed by embedding the first metal material into openings formed in the interlayer insulation film 2 on the mark formation region 12 of the semiconductor substrate 1. That is, the marks 4 are made of a metal material that is the same as that of the contact plugs 3. As shown in FIG. 1, the marks 4 are formed in such a manner that surfaces thereof are flat. While the size of the marks 4 can be designed arbitrarily, it is preferable to form the marks 4 wider than the contact plugs 3. For example, the width of the marks 4 is preferably equal to or larger than 100 nm.

A barrier film 41 is formed between the marks 4 and the interlayer insulation film 2. Similarly to the barrier film 31, the barrier film 41 is made of the barrier metal mentioned above. The barrier film 41 suppresses diffusion of the first metal material that forms the marks 4 to the interlayer insulation film 2. The semiconductor device according to the first embodiment can also be configured without the barrier film 41.

The second alignment marks 5 (hereinafter, “marks 5”) are formed in the interlayer insulation film 2 on the mark formation region 12 of the semiconductor substrate 1. More specifically, the marks 5 are formed so as to be along inner surfaces of openings formed in the interlayer insulation film 2 on the mark formation region 12 of the semiconductor substrate 1, respectively. Therefore, the marks 5 have concaves 51 on surfaces thereof, respectively, unlike the marks 4.

The marks 5 are made of a second metal material. The second metal material can be the same as the first metal material mentioned above or can be different from the first material. For example, Cu, W, Al, or an alloy thereof can be used as the second metal material. While the size of the marks 5 can be designed arbitrarily, it is preferable to form the marks 5 wider than the contact plugs 3. For example, the width of the marks 5 is preferably equal to or larger than 100 nm.

The upper wiring layer 6 includes a contact film 61, an upper wiring 62, and an insulation film 63. The contact film 61 is formed at least on the contact plugs 3, and reduces contact resistances between the upper wiring 62 and the contact plugs 3. The contact film 61 can be made of a metal material such as Ti, TiN, TiO, TaN, WN, or RuO. As shown in FIG. 1, the contact film 61 can be formed on the marks 4 and between the marks 5 and the interlayer insulation film 2. The semiconductor device according to the first embodiment can also be configured without the contact film 61.

The upper wiring 62 made of a metal material (the second metal material) that is the same as that of the marks 5 is formed on the contact film 61. The upper wiring 62 is electrically connected via the contact film 61 to the contact plugs 3. When the semiconductor device according to the first embodiment does not include the contact film 61, the upper wiring 62 is formed directly on the contact plugs 3.

Another semiconductor substrate can be stacked on the upper wiring 62. In this case, the upper wiring 62 can be electrically connected to circuits and terminals formed on the stacked semiconductor substrate. Therefore, the circuits formed on the semiconductor substrate 1 are electrically connected to the circuits formed the upper semiconductor substrate via the lower wiring 15, the contact plugs 3, and the upper wiring 62. As shown in FIG. 1, the upper wiring 62 can be formed on the marks 4.

The insulation film 63 is formed on the upper wiring 62 and is made of an insulator such as SiO₂. The upper semiconductor substrate can be stacked on the upper wiring layer 6 with such a configuration. As shown in FIG. 1, the insulation film 63 can be formed on the marks 4 and 5.

As explained above, according to the semiconductor device of the first embodiment, seams or the like are not formed in the contact plugs 3 and thus it is possible to suppress increase in the resistances of the contact plugs 3 and poor conduction thereof.

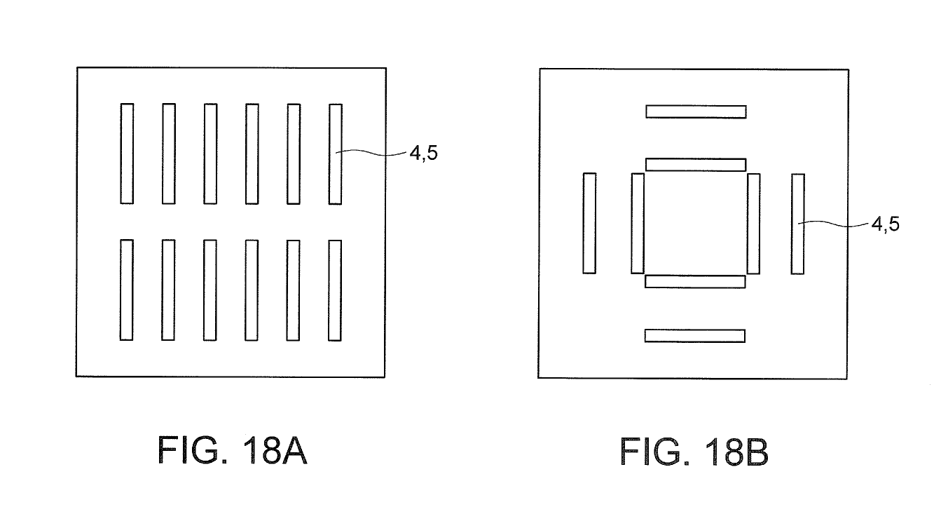

While two contact plugs 3, two marks 4, and two marks 5 are shown in FIG. 1, the numbers thereof can be designed arbitrarily. While one mark 4 and one mark 5 can be formed, it is preferable to provide pluralities of the marks 4 and 5 to improve alignment accuracy. When pluralities of the marks 4 and 5 are formed, for example, the marks 4 and 5 are arranged in string shapes or box shapes in a planar view, respectively. FIG. 18A is a plan view sowing the marks 4 or 5 arranged in a string shape. In FIG. 18A, vertically long marks 4 or 5 are arranged parallel to each other. FIG. 18B is a plan view showing the marks 4 or 5 arranged in a box shape. In FIG. 18B, vertically long marks 4 or 5 and horizontally long marks 4 or 5 are arranged so as to form a rectangle.

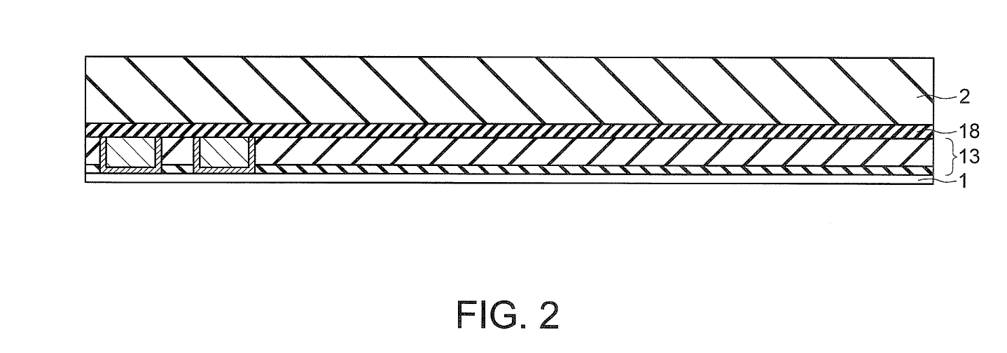

Next, a manufacturing method of the semiconductor device according to the first embodiment is explained with reference to FIGS. 2 to 9. As shown in FIG. 2, the stopper insulation film 18 and the interlayer insulation film 2 are first formed on the lower wiring layer 13. The stopper insulation film 18 and the interlayer insulation film 2 can be formed by a known method such as a CVD method.

Next, openings 32 and 43 are formed in the stopper insulation film 18 and the interlayer insulation film 2. The openings 32 are openings (via holes) for forming the contact plugs 3 and formed so that a surface of the lower wiring 15 is exposed. That is, the openings 32 are formed in the interlayer insulation film 2 on the device region 11 of the semiconductor substrate 1. The openings 43 are openings for forming the marks 4 and formed in the interlayer insulation film 2 on the mark formation region 12 of the semiconductor substrate 1. The openings 43 are formed at predetermined positions with respect to the openings 32. The openings 32 and 43 can be formed simultaneously. In this case, the openings 32 and 43 have substantially identical depths, respectively. The openings 32 and 43 can be formed by a lithographic technique and an etching method.

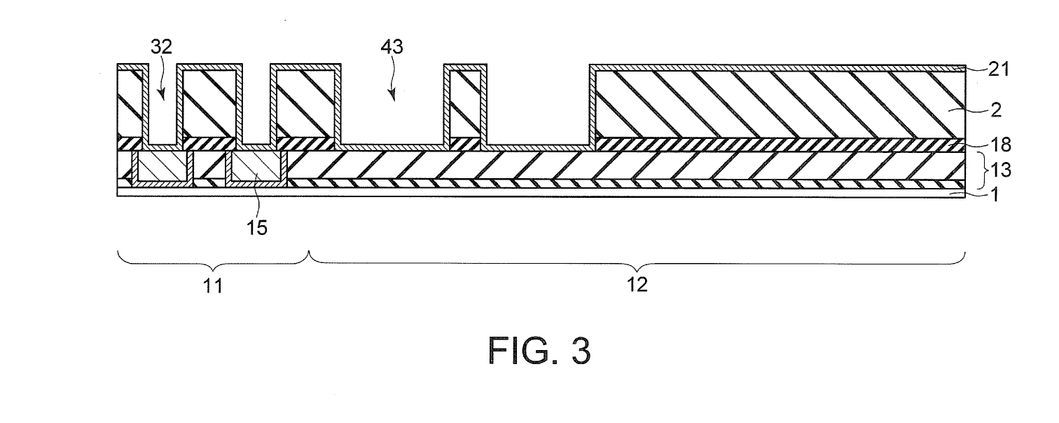

After the openings 32 and 43 are formed, a barrier film 21 is formed as shown in FIG. 3. The barrier film 21 is formed on a surface of the interlayer insulation film 2 and inner surfaces of the openings 32 and 43. The barrier film 21 can be formed by a known method such as the CVD method. When the semiconductor device according to the first embodiment does not include the barrier film 21, this process is omitted.

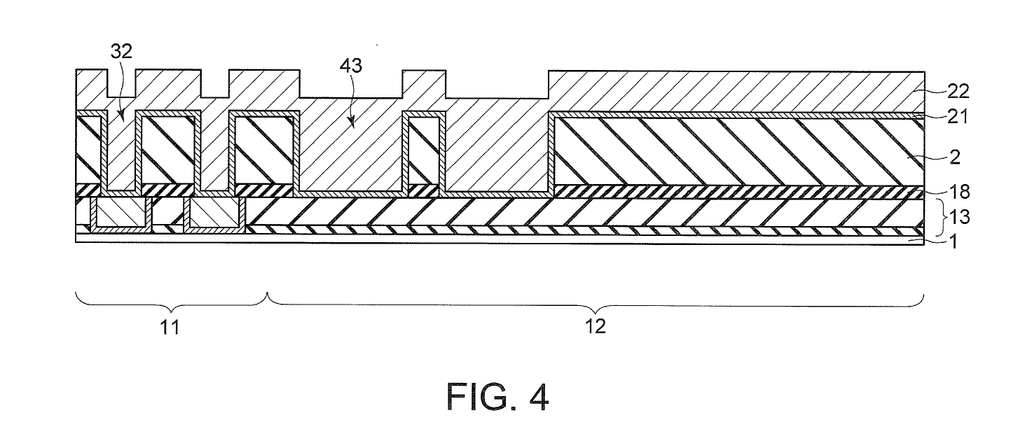

Next, as shown in FIG. 4, a metal material film 22 is formed on the barrier film 21. The metal material film 22 is made of the first metal material mentioned above and is formed in such a manner that the first metal material is embedded into the openings 32 and 43. For such a film formation method, a reflow PVD (Physical Vapor Deposition) method or an electroless plating method can be used.

When the metal material film 22 is formed by the reflow PVD method, film formation is performed in a reduction atmosphere at a high temperature, so that the first metal material flown into the openings 32 and 43 recrystallizes in the openings 32 and 43. As a result, the first metal material can be embedded into the openings 32 and 43. When the metal material film 22 is formed by the reflow PVD method, Cu or Al is preferably used as the first metal material.

When the metal material film 22 is formed by the electroless plating method, the first metal material is formed upward from bottom surfaces of the openings 32 and 43. As a result, the first metal material can be embedded into the openings 32 and 43. When the metal material film 22 is formed by the electroless plating method, Cu or Ni is preferably used as the first metal material.

By forming the metal material film 22 by any of the film formation methods explained above, the contact plugs 3 without any seam or the like can be formed and it is possible to suppress increase in the resistances of the contact plugs 3 and poor conduction thereof.

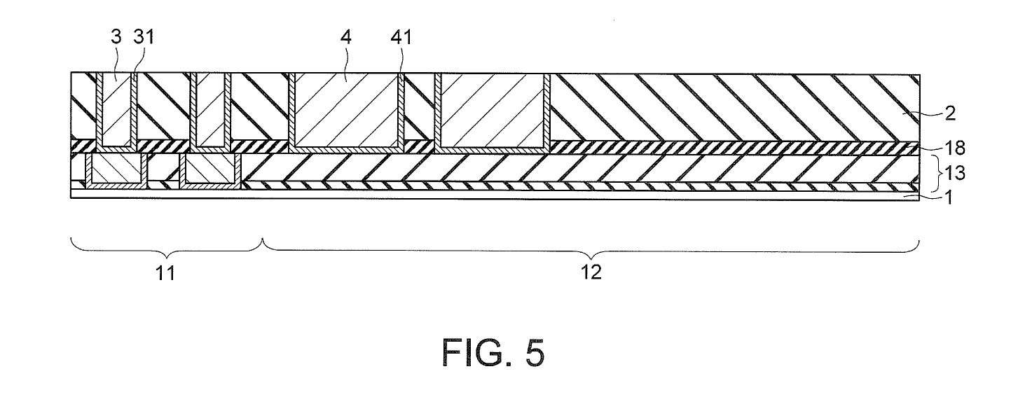

After the metal material film 22 is formed, a surface of the metal material film 22 is polished by a CMP (Chemical Mechanical Polishing) method until the interlayer insulation film 2 is exposed. As a result, as shown in FIG. 5, the contact plugs 3, the barrier film 31, the marks 4, and the barrier film 41 are formed. The surfaces of the contact plugs 3 and the marks 4 are flattened in this process.

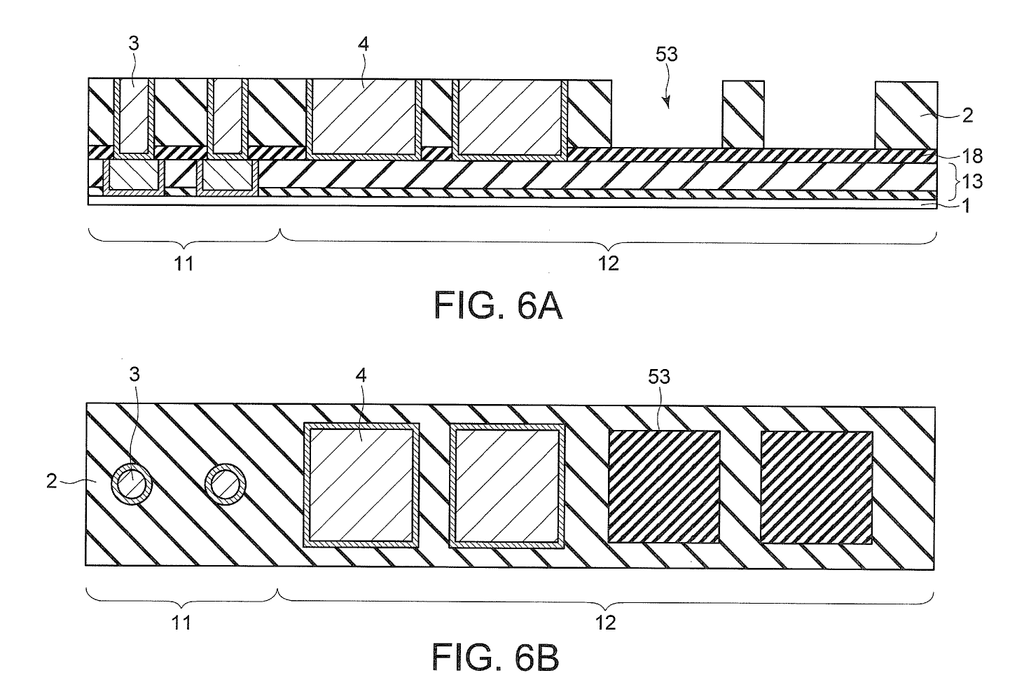

Next, as shown in FIG. 6A, openings 53 are formed in the interlayer insulation film 2. The openings 53 are openings for forming the marks 5 and formed in the interlayer insulation film 2 on the mark formation region 12 of the semiconductor substrate 1. The openings 53 can be formed by a lithographic technique and an etching method.

The openings 53 are formed by using the marks 4 as references. FIG. 6B is a plan view corresponding to FIG. 6A. As shown in FIG. 6B, when the openings 53 are to be formed, the surfaces of the marks 4 are exposed on a surface of the interlayer insulation film 2. Because a color contrast of the surfaces of the marks 4 made of the metal material is different from that of the surface of the interlayer insulation film 2 made of the insulator, positions of the marks 4 can be detected by a camera or the like. By using the detected positions of the marks 4 as references, the openings 53 can be formed at predetermined positions with respect to the contact plugs 3, respectively.

The marks 4 can be designed so as to have an arbitrary width larger than that of the contact plugs 3. Therefore, by designing the marks 4 to have a desired width suitable for alignment, the alignment accuracy of the openings 53 can be improved.

After the openings 53 are formed, a contact film 23 is formed. The contact film 23 is formed by depositing a metal material such as Ti, TiN, TiO, TaN, WN, or RuO so as to cover the surface of the interlayer insulation film 2 and inner surfaces of the openings 53. The contact film 23 can be formed by a known method such as the CVD method. When the semiconductor device according to the first embodiment does not include the contact film 23, this process is omitted.

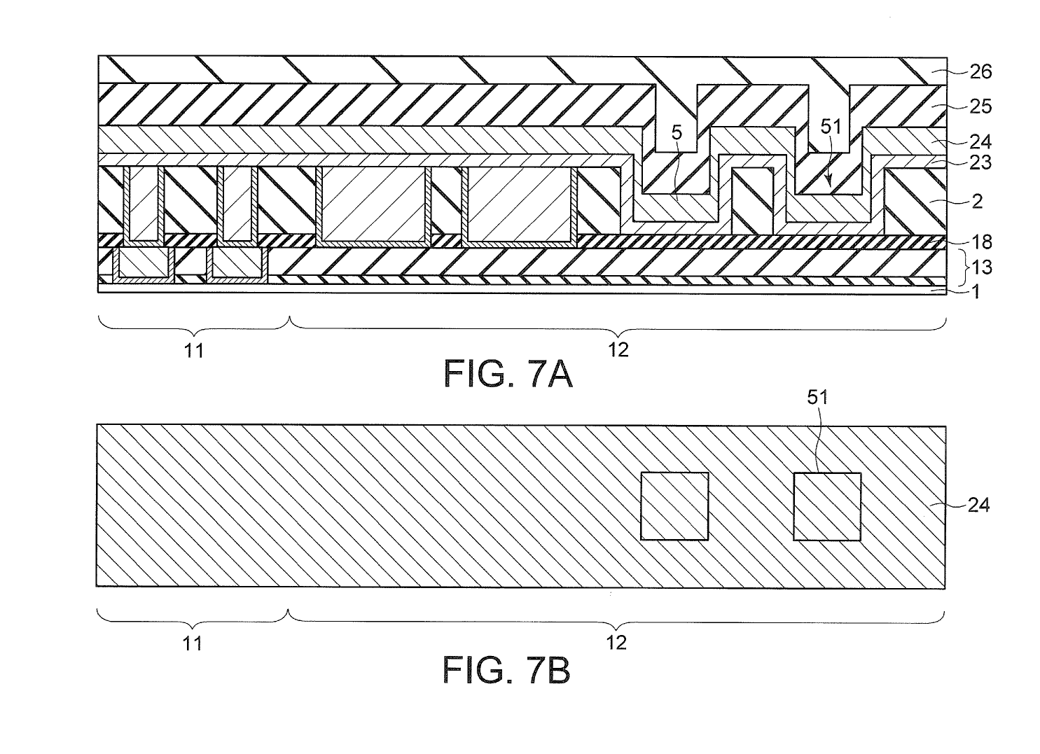

Next, a metal material film 24 is formed on the contact film 23. Film formation of the metal material film 24 ends before the second metal material is filled in the openings 53, so that the marks 5 are formed inside the openings 53, respectively. As a result, the marks 5 are formed inside the openings 53 so as to be along the inner surfaces of the openings 53, respectively. As shown in FIG. 7A, the marks 5 formed as explained above have the concaves 51 at central portions thereof, respectively.

The metal material film 24 formed on the device region 11 of the semiconductor substrate 1 is patterned in the subsequent process to be formed into the upper wiring 62. The metal material film 24 can be obtained by forming the second metal material on the contact film 23 according to an arbitrary method. For example, the metal material film 24 can be formed by the PVD method.

An insulation film 25 is further formed on the metal material film 24. The insulation film 25 is formed by depositing an insulator such as SiO₂. The insulation film 25 can be formed by a known arbitrary method.

After the insulation film 25 is formed, a resist material covers the insulation film 25, thereby forming a resist film 26. The resist film 26 can be formed by a spin coating method or the like.

FIG. 7A is a cross-sectional view showing a state where the resist film 26 is formed, and FIG. 7B is a plan view corresponding to FIG. 7A. As shown in FIG. 7A, it is difficult to see the marks 4. This is because the metal material film 24 does not transmit or hardly transmits visible light and the surfaces of the marks 4 are flat (do not include any concave).

On the other hand, the insulation film 25 and the resist film 26 formed on the metal material film 24 can transmit visible light (are transparent). Furthermore, the concaves 51 are formed in the marks 5, respectively. Accordingly, when the semiconductor device shown in FIG. 7A is seen from above by a camera or the like, stepped parts of the metal material film 24 and the concaves 51 of the marks 5 can be seen as shown in FIG. 7B.

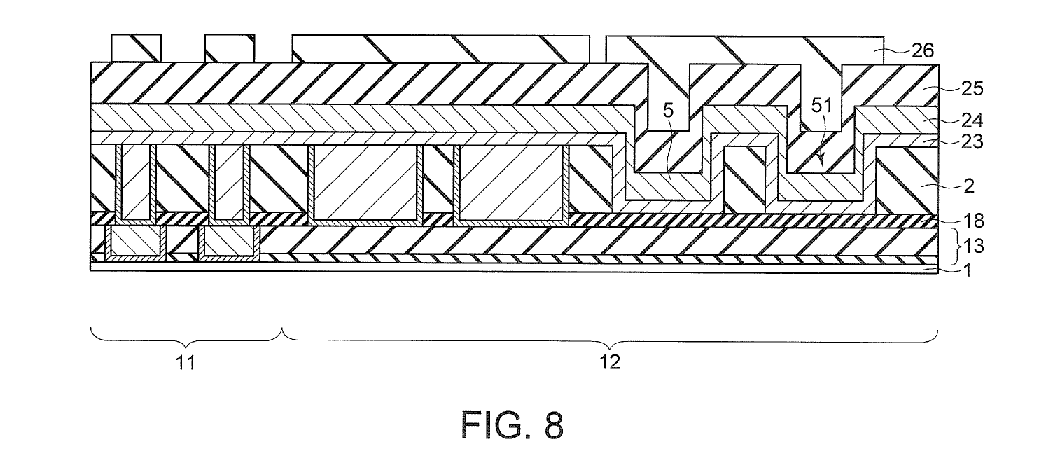

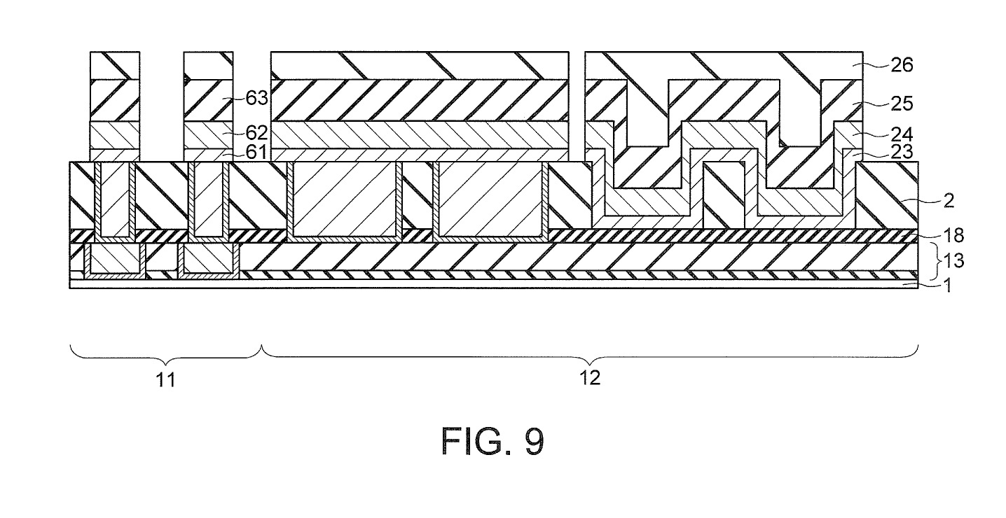

In the first embodiment, the upper wiring layer 6 is pattered by using the marks 5 as references. Specifically, positions of the marks 5 (the concaves 51) are detected first by a camera or the like and then the resist film 26 is patterned based on the detected positions of the marks 5. At this time, as shown in FIG. 8, the resist film 26 is patterned so that the upper wiring layer 6 can be formed in a desired pattern at a desired position. By performing etching by using the resist film 26 patterned as explained above as a mask, the upper wiring layer 6 can be formed in a desired pattern at a desired position as shown in FIG. 9. As a result, the contact plugs 3 can be aligned with the upper wiring layer 6. The marks 5 can be designed to have an arbitrary width.

Therefore, by designing the marks 5 to have a desired width suitable for alignment, the accuracy in alignment between the contact plugs 3 and the upper wiring layer 6 can be improved.

With the processes explained above, the contact film 61, the upper wiring 62, and the insulation film 63 are formed on the contact plugs 3. The contact film 23, the metal material film 24, and the insulation film 25 are formed on the marks 4. Similarly, the contact film 23 is formed between the marks 5 and the interlayer insulation film 2, and the insulation film 25 is formed on the marks 5. After the upper wiring layer 6 is patterned, the resist film 26 is removed by ashing or the like, so that the semiconductor device according to the first embodiment shown in FIG. 1 is formed.

As explained above, according to the manufacturing method of the semiconductor device of the first embodiment, it is possible to prevent seams or the like from being formed within the contact plugs 3. Therefore, it is possible to suppress increase in the resistances of the contact plugs 3 and poor conduction thereof. Further, by using the marks 5, the contact plugs 3 can be aligned with the upper wiring layer 6 accurately. Even when it is difficult to see the marks 4 because of the metal material film 24, the contact plugs 3 can be aligned with the upper wiring layer 6. Therefore, the manufacturing method according to the first embodiment is advantageous when the upper wiring layer 6 is formed by an RIE method.

### Second Embodiment

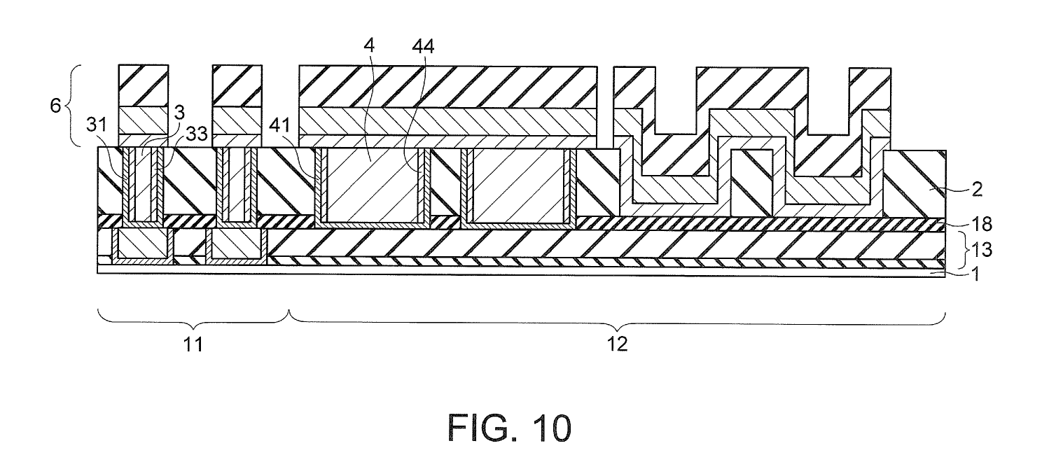

Next, a semiconductor device according to a second embodiment and a manufacturing method thereof are explained with reference to FIGS. 10 to 16. FIG. 10 is a cross-sectional view showing a configuration of the semiconductor device according to the second embodiment. As shown in FIG. 10, the semiconductor device according to the second embodiment includes protection films 33 and 44. Other configurations of the second embodiment are identical to those of the first embodiment.

The protection film 33 is formed between the contact plugs 3 and the barrier film 31 so as to cover side surfaces of the contact plugs 3. The protection film 44 is formed between the marks 4 and the barrier film 41 so as to cover side surfaces of the marks 4. The protection films 33 and 44 are formed to prevent deposition by the CVD method from film-formed portions. For example, the protection films 33 and 44 can be formed by depositing an insulation film such as SiO₂ or SiN.

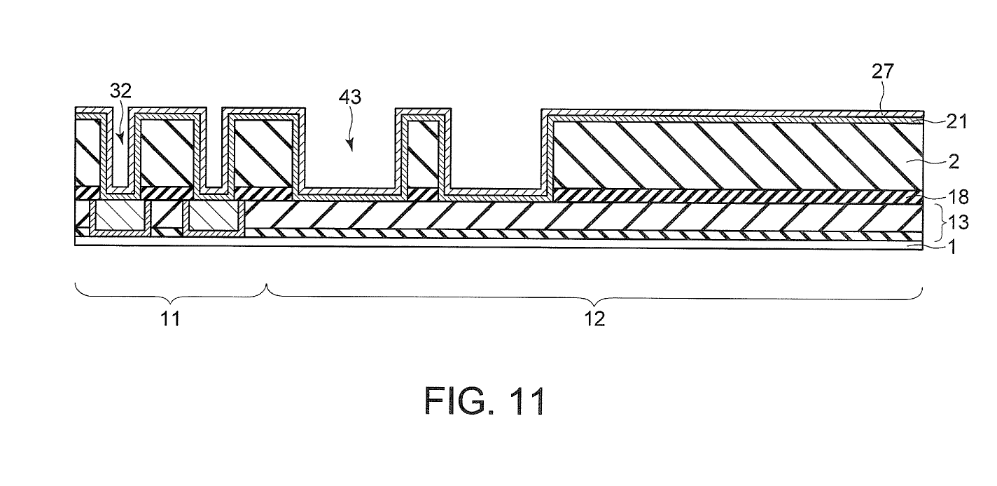

Next, a manufacturing method of the semiconductor device according to the second embodiment is explained with reference to FIGS. 11 to 16. In the following descriptions, explanations of processes identical to those in the first embodiment will be omitted.

First, the stopper insulation film 18 and the interlayer insulation film 2 are formed on the lower wiring layer 13, the openings 32 and 43 are formed in the stopper insulation film 18 and the interlayer insulation film 2, and the barrier film 21 is formed so as to cover the surface of the interlayer insulation film 2 and the inner surfaces of the openings 32 and 43. These processes are identical to those of the first embodiment. Next, as shown in FIG. 11, a protection film 27 is formed by depositing an insulation film such as SiO₂ or SiN on the barrier film 21. The protection film 27 can be formed by a known arbitrary method.

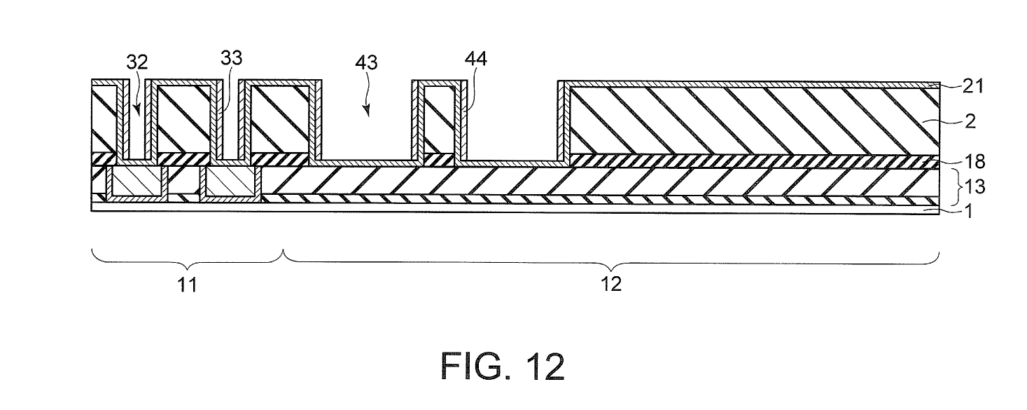

Next, parts of the protection film 27 formed on the surface of the interlayer insulation film 2 and on the bottom surfaces of the openings 32 and 43 are removed by etching back. At this time, an RIE method that can perform anisotropic etching is preferably employed so that parts of the protection film 27 formed on side surfaces of the openings 32 and 43 are not removed. With these processes, the protection films 33 and 44 are formed as shown in FIG. 12.

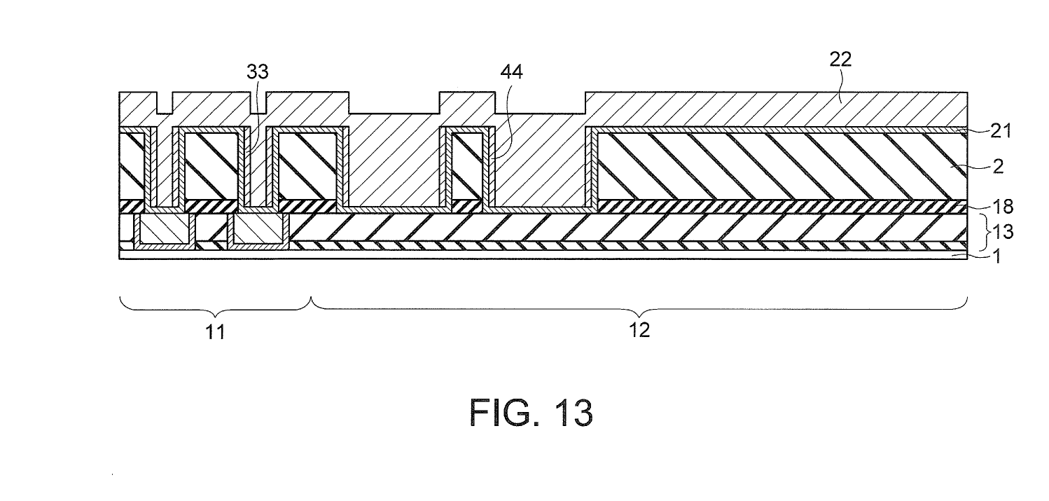

After the protection films 33 and 44 are formed, the metal material film 22 is formed on the barrier film 21 as shown in FIG. 13. The metal material film 22 is made of the first metal material mentioned above and is formed in such a manner that the first metal material is embedded into the openings 32 and 43. For such a film formation method, the reflow PVD method, the electroless plating method, or the CVD method can be used. Methods of forming the metal material film 22 by the reflow PVD method and the electroless plating method are identical to those of the first embodiment.

When the metal material film 22 is formed by the CVD method, because the side surfaces of the openings 32 and 43 are covered by the protection films 33 and 44, respectively, the metal material film 22 is deposited only on the barrier film 21 and formed upward from the bottom surfaces of the openings 32 and 43 due to differences in the seed formation rate and the growth rate at the time of CVD film formation between the barrier film 21 having a conductive property and the insulating protection films 33 and 44 having insulation properties. That is, by forming the protection films 33 and 44, the metal material film 22 can be selectively deposited from the bottom surfaces of the openings 32 and 43. Therefore, the first metal material can be easily embedded into the openings 32 and 43. When the metal material film 22 is formed by the CVD method, Al or W is preferably used as the first metal material.

By forming the metal material film 22 by any of the film formation methods explained above, the contact plugs 3 without any seam or the like can be formed and it is possible to suppress increase in the resistances of the contact plugs 3 and poor conduction thereof.

Subsequent processes are identical to those of the first embodiment. That is, the surface of the metal material film 22 is polished by the CMP method, the openings 53 are formed, the contact film 23, the metal material film 24, the insulation film 25, and the resist film 26 are successively formed, and the upper wiring layer 6 is patterned by using the marks 5 as references. As a result, the semiconductor device according to the second embodiment can be formed.

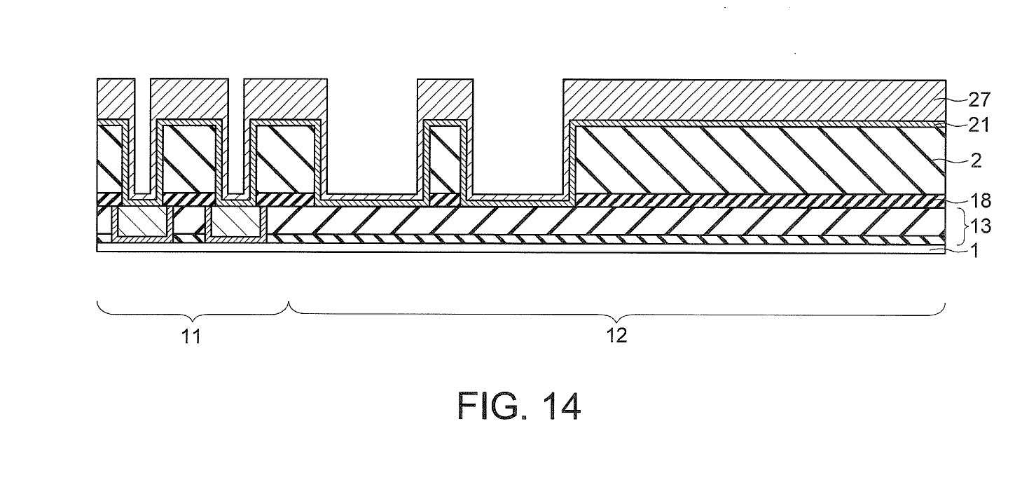

The protection films 33 and 44 can also be formed by other methods. Specifically, SiO₂, SiN, or the like is first deposited on the barrier film 21, thereby forming the protection film 27. At this time, as shown in FIG. 14, the protection film 27 is formed in such a manner that parts of the protection film 27 on the surface of the interlayer insulation film 2 are thicker than parts of the protection film 27 on the bottom surfaces of the openings 32 and 43. This can be realized by using, for example, a difference in the coverage of the CVD method.

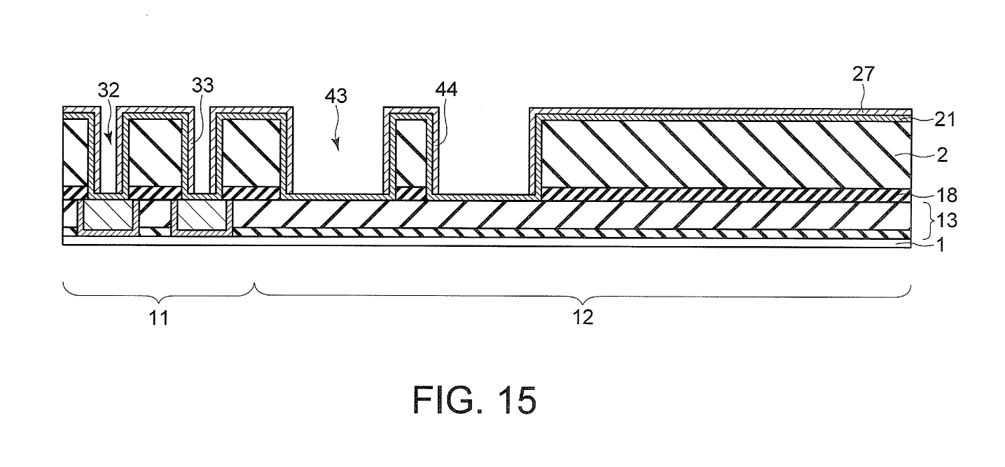

Next, the parts of the protection film 27 formed on the bottom surfaces of the openings 32 and 43 are removed by etching back. At this time, an RIE method that can perform anisotropic etching is preferably employed so that parts of the barrier film 21 formed on the side surfaces of the openings 32 and 43 are not removed. In this manner, the protection films 33 and 44 are formed. Because the parts of the protection film 27 on the surface of the interlayer insulation film 2 are thicker than the parts of the protection film 27 on the bottom surfaces of the openings 32 and 43, even when the parts of the protection film 27 on the bottom surfaces of the openings 32 and 43 are removed, the parts of the protection film 27 on the surface of the interlayer insulation film 2 partly remain without being removed, as shown in FIG. 15. That is, the protection film 27 is formed on the surface of the interlayer insulation film 2.

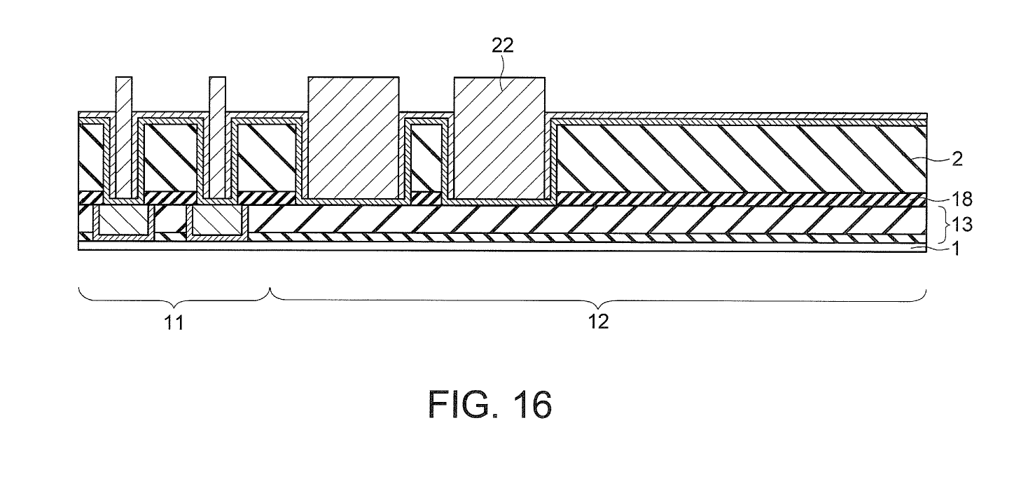

Next, as shown in FIG. 16, the metal material film 22 is formed. When the metal material film 22 is formed by the CVD method, the metal material film 22 is formed from the bottom surfaces of the openings 32 and 43 because the side surfaces of the openings 32 and 43 are covered by the protection films 33 and 44, respectively. Therefore, the contact plugs 3 without any seam or the like can be formed, and it is possible to suppress increase in the resistances of the contact plugs 3 and poor conduction thereof.

Further, because the protection film 27 is formed on the surface of the interlayer insulation film 2, the metal material film 22 is not formed on the interlayer insulation film 2. Therefore, according to this method, the used amount of the first metal material can be reduced.

### Third Embodiment

Next, a NAND flash memory (hereinafter, simply “flash memory”) having the semiconductor device according to the first or second embodiment and the manufacturing method thereof applied thereto is explained as a semiconductor device according to a third embodiment. An example of the flash memory according to the third embodiment is a flash memory that employs a three-dimensional cell stacking technique.

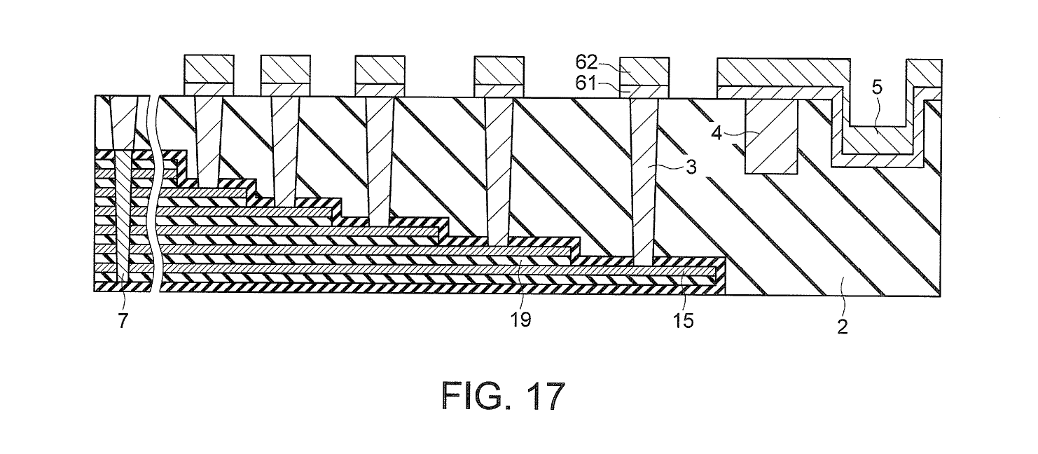

FIG. 17 is a cross-sectional view showing a configuration of the flash memory according to the third embodiment. As shown in FIG. 17, the flash memory according to the third embodiment is configured by three-dimensionally stacking a plurality of memory cells.

More specifically, the flash memory includes a stack structure in which word-line conductive layers each being the lower wiring 15 and insulation films 19 are alternately stacked, a Si pillar 7 that is formed so as to penetrate this stack structure, and the contact plugs 3 that are connected to the word-line conductive layers 15, respectively. The Si pillar 7 is obtained by forming an opening that penetrates the stack structure including the word-line conductive layers 15 and the insulation films 19 from the top one of the word-line conductive layers 15 to the bottom one and embedding Si that contains a dopant into this opening. Bit lines and source lines (both are not shown) are formed on and under the Si pillar 7 that penetrates the word-line conductive layers 15 and electrically connected to the Si pillar 7.

As shown in FIG. 17, a plurality of the contact plugs 3 is formed. The contact plugs 3 are connected to the word-line conductive layers 15, respectively, and the upper wiring 62 is formed on the contact plugs 3. That is, according to the third embodiment, the word-line conductive layers 15 are connected via the contact plugs 3 to the upper wiring 62.

In such a configuration, the aspect ratio (the depth/the width of an opening) of a contact plug 3 that is connected to a lower word-line conductive layer 15 is larger. Therefore, when film formation of a metal material is performed conformally by the CVD method or the like, seams or the like are likely to be formed within the contact plugs 3.

There is a case where a recent downscaled semiconductor device is formed so that the widths of the contact plugs 3 are 10 nm to 20 nm. When the contact plugs 3 are formed in such a downscaled manner, the possibility that seams or the like are formed within the contact plugs 3 becomes higher.

Meanwhile, according to the third embodiment, the contact plugs 3 are formed by the reflow PVD method, the electroless plating method, or a selective CVD method. In this case, a metal material grows from bottom surfaces of contact holes toward openings thereof and does not grow from side surfaces of the contact holes. Therefore, the contact holes are filled with the metal material and it is possible to prevent seams or the like from occurring.

Furthermore, when the contact plugs 3 are formed in a downscaled manner as explained above, high alignment accuracy is required at the time of forming word lines as the upper wiring 62. In the conventional semiconductor device, because alignment is performed by using the marks 4, it is difficult to perform alignment with high accuracy. On the other hand, according to the third embodiment, because alignment between the contact plugs 3 and the upper wiring 62 can be performed by using the marks 5 that are wider than the contact plugs 3, alignment accuracy can be improved.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A semiconductor device comprising:
a semiconductor substrate having a device region and a mark formation region;
an interlayer insulation film on the semiconductor substrate;
a plug made of a first metal material in the interlayer insulation film on the device region of the semiconductor substrate;
a first mark made of the first metal material in the interlayer insulation film on the mark formation region of the semiconductor substrate;
a second mark made of a second metal material in the interlayer insulation film on the mark formation region of the semiconductor substrate and that has a concave on a surface thereof; and
an upper wiring formed on the interlayer insulation film and electrically connected to the plug.

2. The device of claim 1, wherein the first metal material is different from the second metal material.

3. The device of claim 1, wherein the first metal material is same as the second metal material.

4. The device of claim 1, wherein the mark formation region is included in a dicing region of the semiconductor substrate.

5. The device of claim 1, wherein the first and second marks are wider than the plug.

6. The device of claim 1, wherein the plug and the first mark are formed by embedding the first metal material into openings in the interlayer insulation film, respectively.

7. The device of claim 1, wherein the second mark is formed to be along an inner surface of an opening in the interlayer insulation film.

8. The device of claim 1, wherein the upper wiring is made of the second metal material.

9. The device of claim 1, further comprising a protection film that prevents deposition by a CVD method and is formed between the plug and the interlayer insulation film and between the first mark and the interlayer insulation film to cover a side surface of the plug and a side surface of the first mark.

10. The device of claim 1, wherein the semiconductor substrate comprises a lower wiring electrically connected to the plug.

11. A manufacturing method of a semiconductor device, the method comprising:
forming an interlayer insulation film on a semiconductor substrate having a lower wiring;
forming a plug electrically connected to the lower wiring by embedding a first metal material into the interlayer insulation film on a device region of the semiconductor substrate and forming a first mask by embedding the first metal material into the interlayer insulation film on a mark formation region of the semiconductor substrate;
forming a second mark that is made of a second metal material and has a concave on a surface thereof at a predetermined position of the interlayer insulation film on the mark formation region of the semiconductor substrate using the first mark as a reference; and
forming an upper wiring electrically connected to the plug using the second mark as a reference.

12. The method of claim 11, wherein the plug and the first mark are formed by forming openings in the interlayer insulation film and embedding the first metal material into the openings, respectively.

13. The method of claim 11, wherein the plug and the first mark are formed by a reflow PVD method.

14. The method of claim 11, wherein the plug and the first mark are formed by an electroless plating method.

15. The method of claim 12, wherein the plug and the first mark are formed by selectively depositing the first metal material from bottom surfaces of the openings by a CVD method.

16. The method of claim 11, wherein the second mark is formed by forming an opening at a predetermined position of the interlayer insulation film on the mark formation region of the semiconductor substrate using the first mark as a reference and conformally depositing the second metal material on an inner surface of the opening.

17. The method of claim 11, wherein
the upper wiring is formed by
after forming the plug and the first mark,
forming an opening for forming the second mark at a predetermined position of the interlayer insulation film on the mark formation region of the semiconductor substrate using the first mark as a reference,
forming the second mask by depositing the second metal material on an inner surface of the opening and on the interlayer insulation film, and
patterning the second metal material deposited on the interlayer insulation film using the second mark as a reference.

18. The method of claim 11, wherein
the plug and the first mark are formed by
forming openings for forming the plug and the first mark in the interlayer insulation film, respectively,
then forming a protection film preventing deposition by a CVD method on side surfaces of the openings, and
depositing the first metal material from bottom surfaces of the openings by the CVD method.

19. The method of claim 18, wherein
the protection film on the side surfaces of the openings is formed by
after forming the openings for forming the plug and the first mark in the interlayer insulation film,
forming the protection film on inner surfaces of the openings and on the interlayer insulation film, and
removing the protection film formed on the bottom surfaces of the openings.

20. The method of claim 18, wherein
at a time of forming the protection film on inner surfaces of the openings and on the interlayer insulation film,
the protection film is formed to be thicker on a surface of the interlayer insulation film than on the bottom surfaces of the openings.
